(19) United States
(12) Patent Application Publication
(10) Pub. No.: US 2026/0132508 A1
(43) Pub. Date: May 14, 2026

(54) VARIABLE PRESSURE DOSING METHOD AND SYSTEM

(71) Applicant: ASM IP Holding B.V., Almere (NL)

(72) Inventors: Chad Russell Lunceford, Phoenix, AZ (US); Shuaidi Zhang, Chandler, AZ (US); Jonathan Bakke, Phoenix, AZ (US); Paul Ma, Scottsdale, AZ (US)

(21) Appl. No.: 19/378,424

(22) Filed: Nov. 4, 2025

Related U.S. Application Data
(60) Provisional application No. 63/717,525, filed on Nov. 7, 2024.

(51) Int. Cl. C23C 16/455; C23C 16/04; C23C 16/08; C23C 16/40; C23C 16/52; H10P 14/43; H10P 14/60

(52) U.S. Cl. CPC C23C 16/45557; C23C 16/045; C23C 16/08; C23C 16/40; C23C 16/45544; C23C 16/52; H10P 14/43; H10P 14/6334

(57) ABSTRACT

A method of depositing material and a system for depositing material are disclosed. Exemplary methods include dosing a substrate with a precursor and/or reactant while varying a pressure within the reaction chamber.

### CROSS-REFERENCE TO RELATED APPLICATIONS

This application is a nonprovisional of, and claims priority to and the benefit of, U.S. Provisional Patent Application No. 63/717,525, filed Nov. 7, 2024 and entitled “VARIABLE PRESSURE DOSING METHOD AND SYSTEM,” which is hereby incorporated by reference herein.

### FIELD OF DISCLOSURE

The present disclosure generally relates to methods and apparatus for gas-phase processes. More particularly, the disclosure relates to gas-phase methods of depositing material within a gap on a surface of a substrate and to reactor systems to perform such methods.

### BACKGROUND OF THE DISCLOSURE

Gas-phase processes, such as chemical vapor deposition (CVD), plasma-enhanced CVD (PECVD), atomic layer deposition (ALD), and the like are often used to deposit materials onto a surface of a substrate, etch material from a surface of a substrate, and/or clean or treat a surface of a substrate. For example, gas-phase processes can be used to deposit layers of material on a substrate to form semiconductor devices, flat panel display devices, photovoltaic devices, microelectromechanical systems (MEMS), and the like.

In some cases, it may be desirable to fill a gap (e.g., a via or a trench) on a surface of the substrate with material, such as conductive or dielectric material. As device features generally continue to decrease in size, it has become increasingly difficult to fill gaps with material having desired material properties and with desired fill characteristics (e.g., little or no seam and/or void formation). This can be especially so when attempting to fill gaps using conformal deposition techniques for high-stack memory structures-particularly as the number of layers, number of holes, and/or aspect ratios of features, such as gaps, increases.

Techniques to improve filling of gaps on a surface of a substrate include increasing an amount of precursor and/or reactant provided during a deposition process and operating the deposition process at a relatively high pressure. While such techniques can work for some applications, such techniques can increase operating costs and/or have limited ability to fill gaps with material having desired properties. Accordingly, improved methods and reactor systems for depositing material within gaps on a surface of a substrate are desired.

Any discussion of problems and solutions in this section has been solely for the purposes of providing a context for the present disclosure; such discussion should not be taken as an admission that any or all of the discussion was known at the time the invention was made.

### SUMMARY OF THE DISCLOSURE

This section introduces a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure provide methods and reactor systems for depositing material on a surface of a substrate. As set forth in more detail below, exemplary methods and reactor systems are particularly well suited for processes for (e.g., conformally) depositing material within a gap on the surface of the substrate.

In accordance with various embodiments of the disclosure, a method of depositing material within a gap on a surface of a substrate includes providing the substrate within a reaction chamber of a reactor, using a vacuum source, reducing a pressure within the reaction chamber to a first pressure (P1), increasing the pressure within the reaction chamber from P1 toward a second pressure (P2), and while increasing the pressure toward P2, pulsing a precursor into the reaction chamber for a precursor pulse period. In accordance with various examples, the pressure within the reaction chamber continues to increase after the precursor pulse period. In accordance with further examples, the pressure within the reaction chamber continually increases for a pressurization period. The pressurization period can be, for example, between about 1 and about 10 seconds or between about 1 and about 5 seconds. In at least some cases, the step of increasing begins before the step of pulsing the precursor into the reaction chamber. The method can further include decreasing the pressure within the reaction chamber to P3 and after the step of decreasing the pressure within the reaction chamber to P3, increasing the pressure within the reaction chamber to P4. The method can be or include a thermal cyclical deposition process. The material can be or include metallic or dielectric material.

In accordance with further embodiments, a reactor system includes one or more reaction chambers, a precursor gas source, a reactant gas source, a vacuum source, and a controller. The controller can be configured to cause the reactor system to perform a method as described herein.

Both the foregoing summary and the following detailed description are exemplary and explanatory only and are not restrictive of the disclosure or the claimed invention.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with various embodiments of the disclosure.

FIG. 2 illustrates a sequence of steps in accordance with further exemplary embodiments of the disclosure.

FIG. 3 illustrates a reactor system in accordance with additional exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION OF EXEMPLARY EMBODIMENTS OF THE DISCLOSURE

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

As set forth in more detail below, various embodiments of the disclosure relate to a method of depositing material within a gap on a surface of a substrate. The method can be used to deposit material for a variety of applications, such as the formation of semiconductor devices, such as memory devices or the like. However, unless noted otherwise, the invention is not necessarily limited to such examples.

As used herein, the term substrate may refer to any underlying material or materials, including and/or upon which one or more layers can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can include various gaps, such as recesses, vias, spaces between lines, trenches, and the like formed on the surface of the substrate.

In some embodiments, the term film refers to a layer extending in a direction perpendicular to a thickness direction. In some embodiments, layer refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequences, and/or functions or purposes of the adjacent films or layers. Further, a layer or film can be continuous or discontinuous.

In this disclosure, the term gas may refer to material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution device, such as a showerhead, other gas distribution device, or the like, may be used for, e.g., sealing the reaction space, and may include a seal gas, such as a rare gas.

In some cases, such as in the context of deposition of material, the term precursor can refer to a compound that participates in the chemical reaction that produces another compound, and particularly to a compound that constitutes a film matrix or a main skeleton of a film, whereas the term reactant can refer to a compound, in some cases other than precursors, that reacts with the precursor, activates the precursor, modifies the precursor, or catalyzes a reaction of the precursor. In some cases, the terms precursor and reactant can be used interchangeably. The term inert gas refers to a gas that does not take part in a chemical reaction to an appreciable extent, and unlike a reactant, may not become a part of a film matrix to an appreciable extent.

The term cyclic deposition process or cyclical deposition process may refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component. In some cases, an inert gas and/or one or more reactants can continuously flow during multiple cycles of a cyclical process and a precursor can be pulsed. In accordance with examples of the disclosure, a method is a thermal cyclical deposition process. Such a process does not include use of a plasma or the like to excite the precursor and/or reactant. Rather, such a process typically employs a substrate heater or other heater to drive the desired reactions.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like in some embodiments. For example, the term about can refer to +/−20, 10, 5, 2, or 1 percent of a value. Further, in this disclosure, the terms including, constituted by and having and their equivalents can refer independently to typically or broadly comprising, comprising, consisting essentially of, or consisting of in some embodiments. In accordance with aspects of the disclosure, any defined meanings of terms do not necessarily exclude ordinary and customary meanings of the terms.

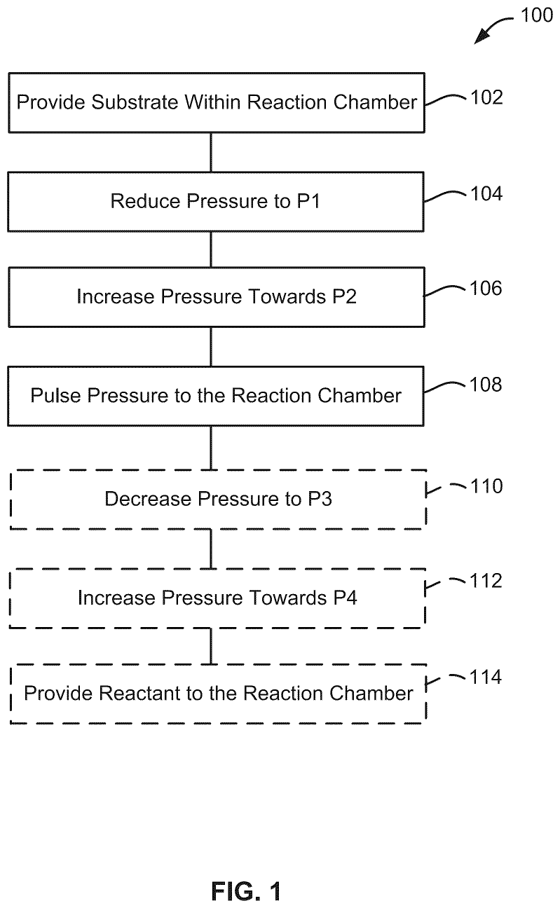

Turning now to the figures, FIG. 1 illustrates a method 100 of (e.g., conformally) depositing material within a gap on a surface of a substrate in accordance with embodiments of the disclosure. Method 100 includes the steps of providing the substrate within a reaction chamber of a reactor (step 102), reducing a pressure within the reaction chamber to a first pressure (P1) (step 104), increasing the pressure within the reaction chamber from P1 toward a second pressure (P2) (step 106), and pulsing a precursor into the reaction chamber for a precursor pulse period (step 108). As illustrated, method 100 can also include reducing a pressure within the reaction chamber to a third pressure (P3) (step 110), increasing the pressure within the reaction chamber from P3 toward a fourth pressure (P4) (step 112), and/or providing a reactant to the reaction chamber (step 114). Method 100 can suitably be used to fill the gap with the material—e.g., with relatively little or no seam or void formation.

During step 102, a substrate is provided within a reaction chamber. The reaction chamber used during step 102 can be or include a reaction chamber of a chemical vapor deposition reactor system configured to perform a cyclical deposition process. The reaction chamber can be a standalone reaction chamber or part of a cluster tool.

Step 102 can include heating the substrate to a desired deposition temperature within the reaction chamber. In some embodiments of the disclosure, step 102 includes heating the substrate to a temperature of less than 800° C. For example, in some embodiments of the disclosure, heating the substrate to a deposition temperature may comprise heating the substrate to a temperature between approximately 20° C. and approximately 900° C., less than 650° C., less than 600° C., less than 550° C., less than 500° C., between about 300° C. and 600° C., between about 300° C. and 650° C., between about 300° C. and 550° C., between about 300° C. and 500° C., or between about 300° C. and 450° C.

In addition to controlling the temperature of the substrate, a pressure within the reaction chamber may also be regulated. For example, in some embodiments of the disclosure, the pressure within the reaction chamber during step 102 and/or at a beginning of step 104 may be less than 760 Torr or between about 0.2 and about 300 Torr, about 5 and about 250 Torr, or about 50 and about 120 Torr.

During step 104, the pressure within the reaction chamber is reduced to a first pressure (P1)—e.g., using a vacuum source, such as a vacuum source described below. The pressure can be reduced to a pressure of less than 100 Torr or between about 0.001 and about 50 Torr, about 0.005 and about 25 Torr, between about 0.01 Torr and 20 Torr, or between about 0.5 Torr and 10 Torr. A temperature within the reaction chamber can be the same or similar to the temperature during step 102.

In accordance with examples of the disclosure, the pressure within the reaction chamber is decreased by (e.g., further) opening a throttle valve downstream of the reaction chamber and upstream of the vacuum source. In accordance with further examples, the throttle valve is opened by a command from a controller to control the pressure within the reaction chamber to P1 as described above.

During step 106, the pressure within the reaction chamber is increased from P1 toward a second pressure (P2). In some cases, P2 may be the same or similar to the pressure within the reaction chamber during step 102. By way of particular examples, P2 is between about 60 Torr and 100 Torr or between about 70 Torr and 90 Torr. In accordance with further particular examples, P1 is less than 20 (e.g., between about 0.01 Torr and 20 Torr or between about 0.5 Torr and 10 Torr) and P2 is greater than 60 Torr (e.g., between about 60 Torr and 100 Torr or between about 70 Torr and 90 Torr). In accordance with further examples, P2 is greater than or equal to two, five, seven, or ten times P1. In some cases, the reaction chamber may not reach P2 during step 106 and/or step 108. In some cases, a command from the controller can attempt to control the pressure to P2 using the throttle valve.

During step 108, a precursor and/or a reactant is pulsed into the reaction chamber for a precursor pulse period. The example described below refers to precursor pulsing. However, examples are not so limited, and the pulses described below can additionally or alternatively include a reactant.

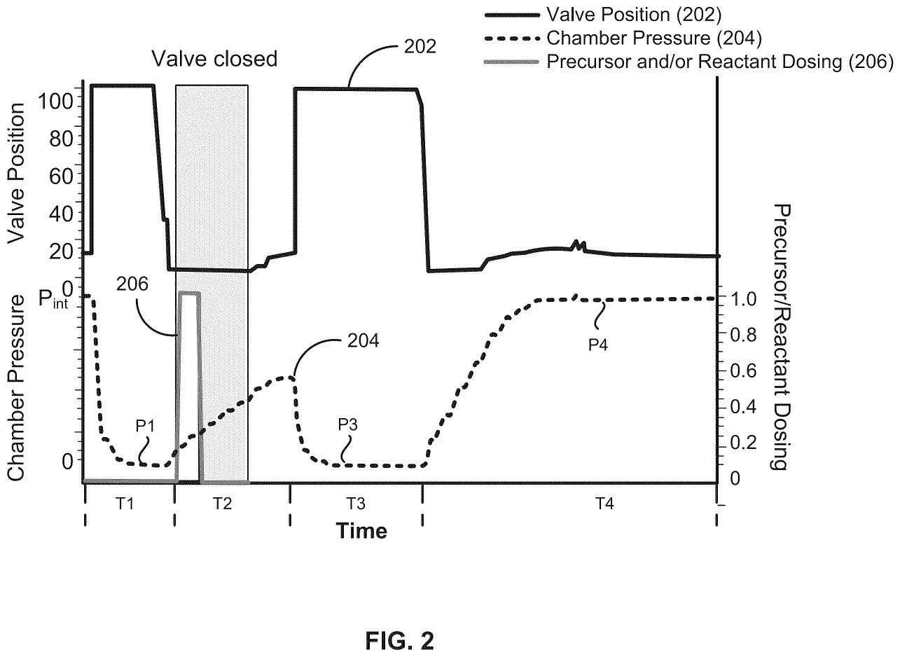

In accordance with examples, the precursor is pulsed to the reaction chamber while increasing the pressure toward P2. In accordance with examples of the disclosure, step 106 begins before the step 108. In accordance with further examples, as described in more detail below in connection with FIG. 2, steps 106 and 108 overlap. In accordance with further examples, the pressure within the reaction chamber continues to increase during step 106 after the precursor pulse step 108 has ended. In accordance with yet additional examples, the pressure within the reaction chamber continually increases for a pressurization period during step 106. The pressurization period can be a period of when the controller sends a signal to the throttle valve to control a pressure within the reaction chamber that is at P1 to pressure P2. Or, the pressurization period can be from a time when the throttle valve begins to control the pressure from P1 toward P2. A duration of the pressurization period can be between about 1 and about 10 or about 1 and about 5 seconds.

A duration of the precursor pulse period can be less than the pressurization period. For example, the duration of the precursor pulse period can be between about 1% and 90% or between about 5% and 30% or between about 10% and 20% of the pressurization period. By way of example, the precursor pulse period can be between about 0.2 and about 10 seconds or between about 0.3 and about 2 seconds.

After step 106 of increasing the pressure within the reaction chamber and/or after step 108, method 100 can include a step 110 of decreasing the pressure within the reaction chamber to a third pressure (P3). P3 can be, for example, about the same as P1. During or at the beginning of step 110, the controller can send a signal to the throttle valve to control a pressure within the reaction chamber—e.g., by opening the throttle valve. This step can be used to, for example, purge the reaction chamber.

After step 110, method 100 can include a step 112 of increasing the pressure within the reaction chamber toward P4. Step 112 can be used to prepare the reaction chamber for a next step, such as repeating steps 104-108 or 110 or a step of providing a reactant.

Although not separately illustrated, method 100 can include a step of decreasing a pressure within the reaction chamber after step 112 and prior to step 114. This step of decreasing the pressure within the reaction chamber after step 112 can be the same or similar to step 104. For example, the pressure can be reduced to a pressure noted above in connection with P1.

During step 114, a reactant can be provided to the reaction chamber. Step 114 can be similar to step 108, except that a reactant is provided to the reaction chamber, rather than a precursor. In some cases, step 114 can differ from step 108. For example, a pressure within the reaction chamber can be substantially constant, rather than increasing, during step 114. In other cases, step 114 can include (e.g., continuously) increasing a pressure (e.g., toward P2 or P4) and optionally continuing after a pulse of the reactant—e.g., as described above in the context of a precursor pulse. P4 can be within the range of P2, described above. In some cases, P4 can be the same as P2.

Method 100 can be used to deposit a variety of materials. For example, method 100 can be used to deposit metal or dielectric materials.

Exemplary metals that can be deposited using method 100 include transition metals, such as molybdenum, tungsten, tantalum, titanium, niobium, scandium, and the like. Exemplary precursors used to deposit metals include metal halide and/or oxyhalides that can include such metals. Particular examples include metal chlorides and metal oxychlorides, such as titanium tetrachloride. Exemplary reactants used to deposit metals include reducing agents. Exemplary reducing agents include one or more of forming gas (H₂+N₂), ammonia (NH₃), hydrazine (N₂H₄), an alkyl-hydrazine (e.g., tertiary butyl hydrazine (C₄H₁₂N₂)), molecular hydrogen (H₂), hydrogen atoms (H), a hydrogen plasma, hydrogen radicals, hydrogen excited species, (e.g., C1-C4) alcohols, (e.g., C1-C4) aldehydes, (e.g., C1-C4) carboxylic acids, (e.g., B1-B12) boranes, or an amine.

Exemplary dielectric materials that can be deposited using method 100 include high-k (e.g., dielectric constant higher than silicon oxide) materials, such as metal oxide dielectric materials. Exemplary metal oxide dielectric materials include transition metal oxides and post transition metal oxides. Particular examples include aluminum oxide, titanium oxide, and the like. Exemplary precursors used to deposit dielectric materials include organometallic compounds, such as C1-C4 alkyl organometallic compounds (e.g., trimethylaluminum). Exemplary reactants used to deposit dielectric materials include oxidizing, nitriding, and/or carbonizing agents.

Exemplary oxidizing agents include one or more of O₂, water (H₂O), hydrogen peroxide (H₂O₂), ozone (O₃), oxides of nitrogen, such as, for example, nitrogen monoxide (NO), nitrous oxide (N₂O), and nitrogen dioxide (NO₂).

Exemplary nitriding agents can be selected from one or more of nitrogen (N₂), ammonia (NH₃), hydrazine (N₂H₄) or a hydrazine derivate, a mixture of hydrogen and nitrogen, nitrogen ions, nitrogen radicals, and excited nitrogen species, and other nitrogen and hydrogen-containing gases. The nitrogen reactant can include or consist of nitrogen and hydrogen. In some cases, the nitrogen reactant does not include diatomic nitrogen.

Exemplary carbonizing agents include acetylene, ethylene, alkyl halide compounds, alkene halide compounds, metal alkyl compounds, and the like. Exemplary alkyl halide compounds include CX₄, CHX₃, CH₂X₂, CH₃X, where X=F, Cl, Br, or I. Exemplary alkene halide compounds include C₂H₃X, C₂H₂X₂, C₂HX₃, and C₂X₄, where X=F, Cl, Br, or I. Exemplary alkyne halide compounds include C₂X₂ and HC₂X, where X=F, Cl, Br, or I. Exemplary metal alkyl compounds include AlMe₃, AlEt₃, Al(iPr)₃, Al(iBu)₃, Al(tBu)₃, GaMe₃, GaEt₃, Ga(iPr)₃, Ga(iBu)₃, Ga(tBu)₃, InMe₃, InEt₃, In(iPr)₃, In(iBu)₃, In(tBu)₃, ZnMe₂, and ZnEt₂.

FIG. 2 illustrates valve position (line 202), reaction chamber pressure (line 204), and precursor/reactant doping (line 206) sequence steps suitable for use with method 100. Valve position can be represented by 0 for closed and 100 for fully opened. In the illustrated example, chamber pressure is represented in Torr. Precursor and/or reactant dosing is represented on a scale of 0 to 1, where 0 represents substantially no flow and 1 represents the full flowrate.

As illustrated, during a period T1, the (e.g., throttle) valve is opened and a pressure within the reaction chamber is reduced to P1. During a period T2, the valve is at least partially closed and a pressure within the reaction chamber increases toward P2, which can be the same as P4. During T2, a precursor and/or reactant can be pulsed to the reaction chamber for a dose period as described above. During T3, the pressure within the reaction chamber can be reduced to a pressure P3—e.g., by opening the valve. During T4, the pressure within the reaction chamber can increase to P4 by closing the valve.

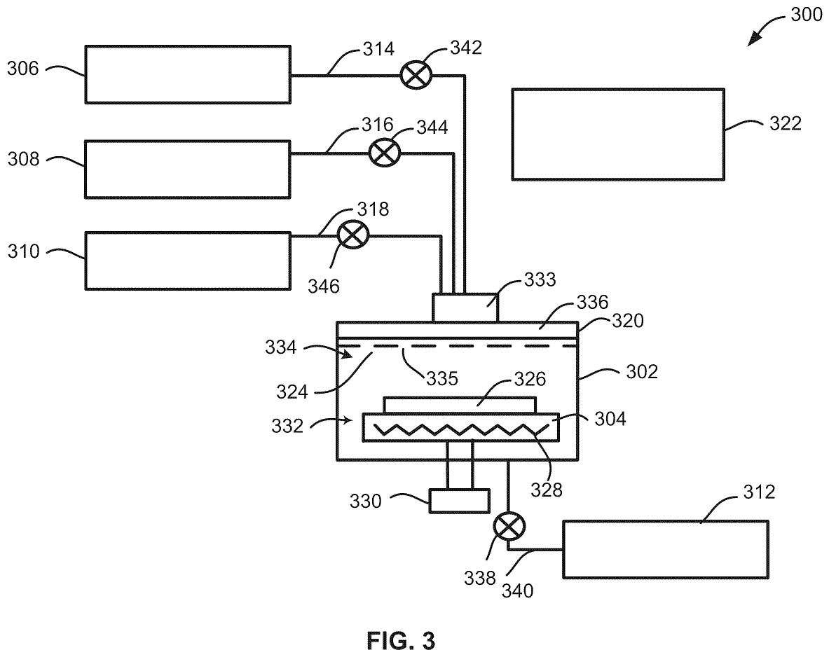

FIG. 3 illustrates an exemplary reactor system 300 in accordance with additional exemplary embodiments of the disclosure. Reactor system 300 includes a reactor 302, a susceptor 304, gas sources 306-310, a gas distribution device 320, vacuum source 312, and controller 322. Although not illustrated, reactor system 300 may additionally include direct and/or remote plasma and/or thermal excitation apparatus for one or more reactants and/or within reactor 302.

Reactor 302 can include a reaction chamber 324 suitable for gas-phase reactions. Reactor 302 can be formed of suitable material, such as quartz, metal, or the like, and can be configured to retain one or more substrates for processing. Reactor system 300 can include any suitable number of reactors 302 and can optionally include one or more substrate handling systems. Reactor 302 can be a standalone reactor or part of a cluster tool.

Reactor 302 can be configured as a cyclical deposition process reactor (e.g., a cyclical CVD reactor), an ALD reactor, or the like. Reactor 302 can be configured to deposit a variety of films or layers, such as those noted above.

Susceptor 304 is configured to retain substrate 326 in place during processing. One or more sections of susceptor 304 can be heated, cooled, or be at ambient process temperature during processing. In accordance with examples of the disclosure, susceptor 304 includes a temperature regulating device 328, such as a heater (e.g., a resistive heater), and/or a cooling device (e.g., a conduit for a cooling medium, such as chilled water).

In the illustrated example, reactor system 300 includes a mechanism 330 to move susceptor 304 from a lower chamber region 332 to an upper chamber region 334. Mechanism 330 can include any suitable apparatus capable of moving susceptor 304. By way of example, mechanism 330 includes a servo motor to drive susceptor 304 along a vertical axis. Mechanism 330 can suitably reside outside reaction chamber 324.

Susceptor 304 can be formed of any suitable material, such as ceramic material, such as boron nitride, aluminum nitride, quartz, and ceramic-coated materials, such as ceramic-coated metals. Susceptor 304 can also include resistive heating material. Exemplary materials suitable for resistive heating material include tungsten (W), nichrome (NiCr), cupronickel (CuNi), graphite, molybdenum disilicide (MoSi) or any other suitable heater material. The resistive heating material can be coated onto (e.g., patterned onto), for example, ceramic or ceramic-coated metal. Susceptor 304 can include an additional protective layer formed overlying the resistive heating material. The protective layer can be formed of, for example, ceramic material.

Gas sources 306-310 can include any suitable vessels and respective material contained therein. By way of examples, gas source 306 can include a precursor, gas source 308 can include a reactant, and gas source 310 can include an inert gas. Gas sources 306-310 can be coupled to reaction chamber 324 via gas distribution device 320.

Gas distribution device 320 is configured to receive and facilitate distribution of one or more gases to reaction chamber 324 during substrate processing. Gas distribution device 320 can include an inlet 333 and a plurality of holes 335 coupled to a plenum 336.

Vacuum source 312 can include one or more vacuum sources. Exemplary vacuum sources include one or more dry vacuum pumps and/or one or more turbomolecular pumps. A (e.g., throttle) valve 338 can be in a line that fluidly couples reaction chamber 324 to vacuum source 312.

Controller 322 can be configured to perform various functions and/or steps as described herein. For example, controller 322 can be configured to perform the method described in connection with FIG. 1 and/or the sequence described in connection with FIG. 2. Controller 322 can include one or more microprocessors, memory elements, and/or switching elements to perform the various functions. Although illustrated as a single unit, controller 322 can alternatively comprise multiple devices. By way of examples, controller 322 can be used to control gas flow of one or more gases from sources 306-310 via one or more of lines 314, 316, 318 and valves 342, 344, 346, to move susceptor 304 between a first position, to control a pressure within reaction chamber 324 (e.g., using valve 338), and/or to pulse a reactant and/or precursor (e.g., using one or more of valves 342-346) as described herein.

Although exemplary embodiments of the present disclosure are set forth herein, it should be appreciated that the disclosure is not so limited. For example, although the assemblies, reactors, systems, and methods are described in connection with various specific configurations, the disclosure is not necessarily limited to these examples. Various modifications, variations, and enhancements of the exemplary assemblies, reactors, systems, and methods set forth herein may be made without departing from the spirit and scope of the present disclosure.

The subject matter of the present disclosure includes all novel and nonobvious combinations and subcombinations of the various steps, systems, assemblies, reactors, components, and configurations, and other features, functions, acts, and/or properties disclosed herein, as well as any and all equivalents thereof.

1. A method of depositing material within a gap on a surface of a substrate, the method comprising:
providing the substrate within a reaction chamber of a reactor;
using a vacuum source, reducing a pressure within the reaction chamber to a first pressure (P1);
increasing the pressure within the reaction chamber from P1 toward a second pressure (P2); and
while increasing the pressure toward P2, pulsing a precursor into the reaction chamber for a precursor pulse period.

2. The method of claim 1, wherein the pressure within the reaction chamber continues to increase after the precursor pulse period.

3. The method of claim 1, wherein the pressure within the reaction chamber continually increases for a pressurization period.

4. The method of claim 3, wherein a duration of the pressurization period is between about 1 and about 10 seconds or between about 1 and about 5 seconds.

5. The method of claim 1, wherein P2 is greater than or equal to five times P1.

6. The method of claim 1, wherein a duration of the precursor pulse period is between about 0.2 seconds and about 10 seconds or between about 0.3 and about 2 seconds.

7. The method of claim 1, wherein P1 is between about 0.01 Torr and 20 Torr or between about 0.5 Torr and 10 Torr.

8. The method of claim 1, wherein P2 is between about 60 Torr and 100 Torr or between about 70 Torr and 90 Torr.

9. The method of claim 1, wherein P1 is less than 20 Torr and P2 is greater than 60 Torr.

10. The method of claim 1, wherein the step of increasing begins before the step of pulsing the precursor into the reaction chamber.

11. The method of claim 1, further comprising, after the step of increasing the pressure within the reaction chamber, a step of decreasing the pressure within the reaction chamber to a third pressure (P3).

12. The method of claim 11, further comprising a step of, after the step of decreasing the pressure within the reaction chamber to P3, increasing the pressure within the reaction chamber to P4.

13. The method of claim 1, wherein the method is a thermal cyclical deposition process.

14. The method of claim 1, comprising conformally depositing the material within the gap.

15. The method of claim 14, comprising filling the gap with the material.

16. A method of conformally depositing a material within a gap on a surface of a substrate, the method comprising:
providing the substrate within a reaction chamber of a reactor;
reducing a pressure within the reaction chamber to a first pressure (P1);
increasing a pressure within the reaction chamber from P1 toward a second pressure (P2); and
while increasing the pressure toward P2, pulsing a precursor into the reaction chamber for a precursor pulse period.

17. The method of claim 16, wherein the pressure within the reaction chamber continually increases for a pressurization period.

18. The method of claim 16, wherein the material comprises a metal.

19. The method of claim 16, wherein the material comprises a dielectric material.

20. A reactor system comprising:
a controller configured to perform the method of claim 16; and
the reactor.
